(19) United States
(12) Patent Application Publication
(10) Pub. No.: US 2016/0248292 A1
(43) Pub. Date: Aug. 25, 2016

(54) ELECTRONIC CONTROL APPARATUS, MOTOR CONTROL APPARATUS AND ELECTRIC FLUID PUMP

(71) Applicant: HITACHI AUTOMOTIVE SYSTEMS, LTD., Hitachinaka-shi (JP)

(72) Inventor: Kenya TAKARAI, Honjo-shi (JP)

(73) Assignee: HITACHI AUTOMOTIVE SYSTEMS, LTD., Hitachinaka-shi (JP)

(21) Appl. No.: 15/047,079

(22) Filed: Feb. 18, 2016

(30) Foreign Application Priority Data
Feb. 19, 2015 (JP) 2015-030112

(51) Int. Cl. H02K 5/08; H05K 5/03; H05K 5/02; H05K 5/06; H02K 11/33; H02K 11/40

(52) U.S. Cl. CPC H02K 5/08; H02K 11/33; H02K 11/40; H05K 5/0247; H05K 5/061; H05K 5/03

(57) ABSTRACT

An electronic control apparatus comprises a housing of synthetic resin, a cover of metallic material, fixed to the housing by a fastening bolt, and an electronic control section enclosed in an interspace formed between the housing and the cover. A conductive gasket is interposed between a joint surface of the housing and a joint surface of the cover, and arranged to ground the cover electrically through the conductive gasket, to relieve static electricity from the metallic cover to a ground or a main body of a vehicle.

### TECHNICAL FIELD

The present invention relates to control apparatus such as electronic control apparatus, motor control apparatus and electric fluid motor.

### BACKGROUND ART

Recently, with increase in demand for lower fuel consumption of motor vehicles, there is a tendency to use a motor such as brushless motor widely in various control mechanisms in the motor vehicles, and the motor is integrated with a drive control device for controlling the motor, into a compact unit.

For example, the function of idle stop is widely used in motor vehicles and the practical use of hybrid vehicles is spreading. In these vehicles, when an internal combustion engine is stopped, a mechanical fluid pump driven by the engine is also stopped. Therefore, another source for driving a fluid pump is required besides the internal combustion engine. Furthermore, electric vehicles and hybrid vehicles require a driving motor, its drive control apparatus and a cooling water pump for cooling a battery. From such a background, there is a tendency of the increasing use of electric fluid pump such as a pump including an impeller driven by an electric motor.

Recent electric fluid pumps are produced often in the form of an integrated unit integrated with a drive control section for supplying a controlled driving current to windings of the motor. The integration of the drive control section with the electric fluid pump is intended to minimize adverse influence of external noise by reducing the length of wiring between the windings and drive control section, to reduce the wiring between the windings and drive control section, to reduce the cost for wiring, to facilitate calibration between the pump section and the drive control section, and/or to improve operability and handling ease.

A Japanese Patent Document, JP 2010-144693A (Patent Document 1) shows an electric fluid pump including an impeller received in an pump chamber, a rotor received in a rotor chamber communicating with the pump chamber, a stator including windings received in a chamber separated liquid-tightly from the rotor chamber, a drive control section fixed to a motor housing made of resin, and a cover covering the drive control section and the motor section.
Patent Document 1: JP2010-144693A (≈US2010/0158703A1)

### SUMMARY OF THE INVENTION

In an electronic control apparatus such as an electric fluid pump including therein a drive control section integrally, the drive control section is mounted on a motor section formed by molding of synthetic resin, and covered by a metallic cover fastened to the motor section. The metallic cover of metallic material is employed to use as a radiator plate for dissipating heat generated in the drive control section, to the outside. The drive control section includes an inverter circuit including switching devices formed by insulated gate bipolar transistors (IGBTs), and the switching devices of the inverter circuit generate heat. The metallic cover is used to dissipate heat generated by these switching devices.

In the electric fluid pump of this type, static electric charge is created and accumulated to a level of a high voltage in the metallic cover. The static electricity of the high voltage may cause electric discharge impairing the function of electric devices in the drive control section inside the cover and even damage the electric devices in an extreme case.

Therefore, there is required measure for releasing the static charge accumulated in the cover, to a vehicle body, to avoid adverse influence of the static electricity on the electric devices.

As the measure to remove the electric charge accumulated in the cover, there are a method of providing, along the side surface of the electric fluid pump, a coated copper wire connecting the metallic cover 31 to a part of the internal combustion engine for grounding, and a method of providing, near the metallic cover, a discharge terminal connected to a ground side of the power supply.

However, in the case of the coated wire connecting the controller cover to part of the internal combustion engine for grounding, the durability is poor because of the coated wire exposed to the outside, and another protective member is required for protecting the coated wire in order to improve the durability. Therefore, this method increases the number of required component parts and the number of assembly steps, and causes an increase of the production cost.

In the case of the discharge terminal near metallic cover for grounding to the power supply ground, the accumulation of static charge to a predetermined threshold level is required and a serge noise at the time of discharge could impair the performance of the electric devices in the drive control section.

Furthermore, the complicated construction is disadvantageous to the motor control apparatus required to reduce the production cost by decreasing the number of component parts and the number of production steps. Accordingly, it is required to relieve the static charge from the metallic cover to the ground side with a simple construction without increasing the number of component parts.

The above-mentioned problem arises not only in the integrated electric fluid pump including the pump and the drive control section integrally as a unit, but also in an electronic control apparatus of a separate type including a control circuit section disposed in a casing.

It is an object of the present invention to provide a novel apparatus, such as electronic control apparatus, motor control apparatus and electric fluid pump, for relieving static charge from a metallic cover to a reference point serving as a ground, such as a vehicle body, with a simple construction.

According to the present invention, a conductive gasket is interposed between a joint surface of a resin housing and a joint surface of a metallic cover, and arranged to ground the cover electrically through the conductive gasket.

The conductive gasket has a function of serving as a gasket and a function of relieving static charge.

### BRIEF EXPLANATION ON THE DRAWINGS

FIG. 1 is an axial sectional view of an electric fluid pump used for an internal combustion engine, to which the present invention is applied.

FIG. 2 is an enlarged sectional view showing a part of the electric fluid pump according to a first embodiment of the present invention.

FIG. 3 is an enlarged sectional view showing a joining state of a fastening bolt and a conductive gasket shown in FIG. 2.

FIG. 4 is a perspective view of the conductive gasket shown in FIG. 3.

FIG. 5 is a sectional view taken across a line A-A in FIG. 4.

FIG. 6 is a sectional view taken across a line B-B in FIG. 4.

FIG. 7 is a sectional view taken across a line C-C in FIG. 4.

FIG. 8 is a perspective view of an electronic control apparatus according to a second embodiment of the present invention.

### DETAILED DESCRIPTION OF THE INVENTION

Following is explanation on embodiments according to the present invention, with reference to the drawings. However, the present invention is not limited to the following embodiments. Various modifications and applications are possible under the technical concept of the present invention, and included in the purview of the present invention.

### First Embodiment

In the following embodiment, the present invention is applied to a motor control apparatus including an electric fluid pump and a drive control device united as a unit. However, the present invention is not limited to the motor control apparatus of this type. The present invention is applicable to various electronic control apparatus and to various motor control apparatus such as an electric power steering apparatus, for example.

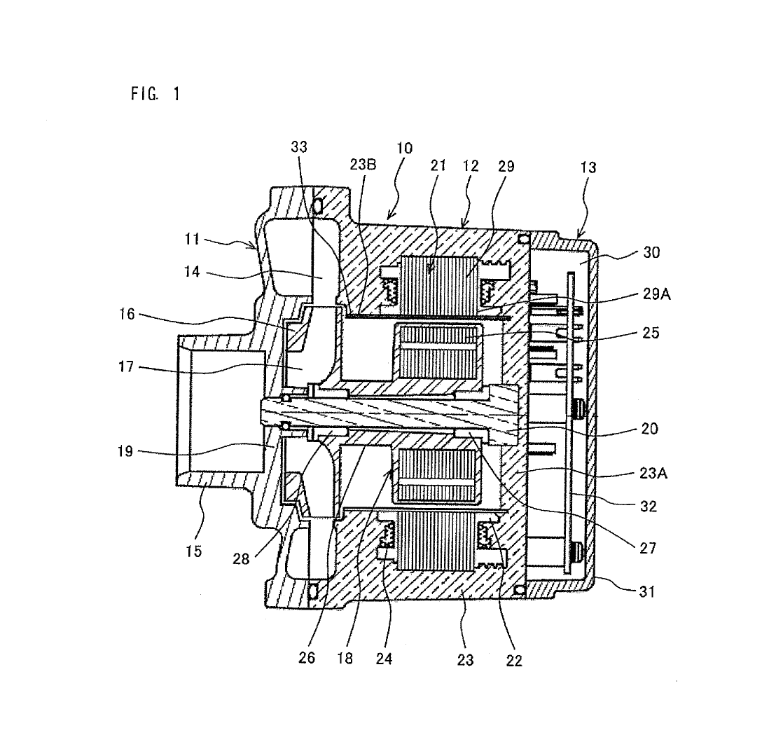

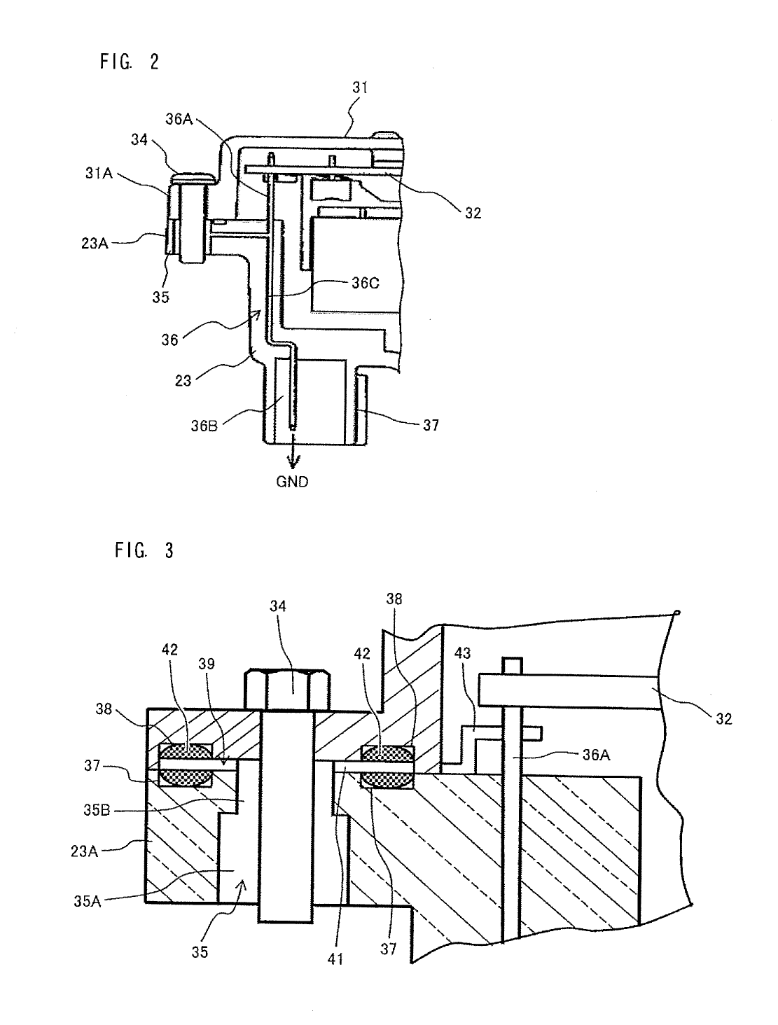

FIG. 1 is a sectional view showing the overall structure of an electric fluid pump according to a first embodiment of the present invention, and FIGS. 2-7 are views more in detail. The electric fluid pump shown in FIG. 1 is a cooling pump which uses a cooling water as an operating fluid, and which is adapted to be incorporated in a cooling water circulating circuit connected with a heat exchanger in the form of a radiator. For example, this electric fluid pump can be used as water pump for supplying the cooling water to an internal combustion engine, a driving motor, an inverter, etc. in a hybrid vehicle.

The electric fluid pump 10 according to this embodiment is an assembly of a pump section 11, a motor section 12 serving as a drive section for driving the pump section 11, and a drive control section 13 for controlling the operation of motor section 12. These sections 11, 12 and 13 are united as a single assembly.

The pump section 11 includes a pump housing 15 defining a pump chamber 14, and an impeller 16 received rotatably in pump chamber 14.

The pump housing 15 includes an inlet opening (not shown) opening into the pump chamber 14, and an outlet opening (not shown) opening from a peripheral portion of pump chamber 14 to the outside of pump chamber 14. The pump section 11 of this example is a centrifugal pump raising the pressure of the liquid in the radial direction by the rotation of impeller 16. By the rotation of impeller 16, the cooling water is sucked from the inlet opening into pump chamber 14, and discharged under pressure from the outlet opening through a discharge passage on the outer circumferential side of impeller 16.

Impeller 16 is a wheel having a plurality of vanes 17. Impeller 16 is integral and coaxial with a rotor 18 of the motor section 12. Impeller 16 is disposed in pump chamber 14. Vanes 17 are arranged radially around a center axis of rotor 18. Each vane 17 of this example extends radially outwards in a slanting manner that the vane 17 inclines to the direction opposite to the rotational direction of impeller 16. As a whole, vanes 17 are arranged in a volute or swirl form.

The pump housing 15 is formed integrally with a movement limiting member 19 for limiting axial movement of the rotor 18 and impeller 16. The movement limiting member 19 includes a center hole into which a first (left) end of a support shaft 20 of rotor 18 is inserted, so that the end of support shaft 20 is supported by the movement limiting member 19.

The motor section 12 of this example is an inner rotor type brushless DC motor. Motor section 12 includes a stator 21 shaped like a hollow cylinder, the rotor 18 surrounded by stator 21, a motor housing 23 defining a motor chamber 22 for enclosing the stator 21 ad rotor 18, and the support shaft 20 provided in motor housing 23 and arranged to support the rotor 18 rotatably.

The motor housing 23 is a resin housing made of a synthetic resin. Stator 21 is formed integrally in motor housing 23 by insert molding. Similarly, the rotation shaft 20 is formed integrally by insert molding, in motor housing 23. Motor housing 23 of the synthetic resin includes a cylindrical wall having a hollow cylindrical shape and surrounding the stator 21, and a bottom or end 23A closing one end of the hollow cylindrical shape formed by the cylindrical wall. In this example, the bottom 23A has a shape like a circular plate and includes a center portion supporting a second (right) end of the rotation shaft 20 so that rotation shaft 20 stands upright from bottom 23A. The second end of rotation shaft 20 is buried in the synthetic resin of bottom 23A.

The stator 21 includes a plurality of windings 24 to produce magnetic flux on the inner circumferential side by receiving the supply of current. The rotor 18 includes a pole holding portion 25 and a shaft portion 26 as an integral unit. In this example, rotor 18 is formed integrally with impeller 16 by injection molding of synthetic resin, for example. The pole holding portion 25 includes permanent magnet(s). Pole holding portion 25 is firmly attached in by the synthetic resin in rotor 18. Since rotor 18 contacts with the cooling water, the pole holding portion 25 is covered with the synthetic resin. As another example, the impeller 16 may be formed as a member separate from rotor 18, and fastened to rotor 18.

The pole holding portion 25 of rotor 18 is a cylindrical member disposed to confront radially the inside circumferential surface of stator 21 across a minute clearance (air gap). Pole holding portion 25 includes therein a plurality of magnetic poles (permanent magnets arranged so that the N and S poles are arranged alternately in the circumferential direction) corresponding to the plurality of the windings 24.

The shaft portion 26 of rotor 18 serves as a shaft for transmitting a driving force to rotate impeller 16. Shaft portion 26 is in the form of a hollow shaft coaxial with the pole holding portion 25. Shaft portion 26 is formed with a first bearing hold portion holding a a first bearing 27 near the pole holding portion 25 and a second bearing hold portion holding a second bearing 28 near the impeller 16. The first and second bearings 27 and 28 are attached to rotor 18, and these bearings 27 and 28 are sliding bearings. The diameter of the inside circumference of each of the first and second bearing 27 and 28 is slightly greater than the diameter of support shaft 20.

The support shaft 20 extends through a center axial hole formed in rotor 18 at the center. Rotor 18 is mounted rotatably on support shaft 20 through first and second bearings 27 and 28 which are supported fixedly by rotor 18, and arranged to slide on support shaft 20. There is a small clearance between the outside circumferential surface of support shaft 20 and the inside circumferential surfaces of first and second bearings 27 and 28.

The stator 21 includes an iron core 29 formed integrally with a plurality of salient poles 29A and the windings 24 wound around the salient poles 29a, respectively, through bobbins of synthetic resins. The rotor 18 is located on the inner circumferential side of teeth formed, in the shape of circular arc, in the salient poles 29A. Therefore, the rotor 18 is rotated by supplying electric power sequentially to the windings 24.

The drive control section 13 is attached to the bottom 23A of motor housing 23. The bottom 23A includes an inner surface facing toward rotor 18 and an outer surface facing in the opposite direction away from rotor 18. Drive control section 13 is fastened to the outer surface of bottom 23A. Drive control section 13 serves as a driver for supplying a driving current for the motor section 12. Drive control section 13 includes a controller cover 31 defining a board receiving chamber 30, and a control board 32 disposed in the board receiving chamber 30 and arranged to support electronic parts. The controller cover 31 is a metallic housing member made of a metallic material such as aluminum alloy, and adapted to serve as a radiator plate for dissipating heat generated in drive control section 13, to the outside.

The control board 32 is a board on and in which electric or electronic device(s) (such as CPU and transistors) are mounted. These circuit elements and capacitor(s) form a converter and a control circuit. The converter receives power from a dc power source in the form of a battery and supplies ac power to the windings 24 of motor section 12. The control circuit includes a microcomputer and other components, for controlling the on-off state of IGBT(s) of the converter.

A partition member 33 is disposed between stator 21 and rotor 18. This partition member 33 is made of metal sheet having a thin section and shaped like a hallow cylinder extending straight from a first open end 33A to a second open end 33B in the axial direction of the rotor 18. The first open end 33A of partition member 33 is joined to a side portion 23B of motor housing 23 located axially between stator 21 and impeller 16, and the second open end 33B of partition member 33 is buried in bottom 23A of motor housing 23. It is optional to employ an arrangement in which the first open end 33A is also buried in the side portion 23B of motor housing 23. In either case, both of the first and second open ends 33A and 33b are joined liquid-tightly to the synthetic resin of motor housing 23 directly.

Rotor 18 is disposed in partition member 33 as shown in FIG. 1, and a coolant such as cooling water is introduced into the inside of partition member 33. The inside circumferential surface of the arched teeth formed in the salient poles 29A of stator 21 are formed in the form of a circular arc conforming to the outside circumferential surface of partition member 33 and set in metal-to-metal contact with the outside circumferential surface of partition member 33. Therefore, heat due to copper loss of the windings 24 and heat of the internal combustion engine incoming from the surrounding is conducted through the salient poles 29A to partition member 33, and further conducted to the cooling water for heat dissipation.

In the thus-constructed electric fluid pump 10, static electricity is generated occasionally on or in the surface of pump 10, and static charge is accumulated to a level of a high voltage in the controller cover 31, as mentioned before. The buildup of high voltage static charge can impair the operation of an electric device in drive control section 13 and even damage the electric device in an extreme case if the high voltage static charge flows by discharge into the electric device.

As measure to remove the electric charge accumulated in controller cover 31 by the flow of excess charge to the main body of the motor vehicle serving as a ground, there are the method of providing, along the side surface of electric fluid pump 10, a coated copper wire connected with the metallic controller cover 31, and disposed in part of the internal combustion engine, and a method of providing, near the metallic controller cover 31, a discharge terminal connected to a power supply ground, as mentioned before.

However, in the case of the coated wire connecting the controller cover 31 to part of the internal combustion engine for grounding, the durability is poor because of the coated wire exposed to the outside, and another protective member is required for protecting the coated wire in order to improve the durability. Therefore, this method increases the number of required component parts and the number of assembly steps, and causes an increase of the production cost.

In the case of the discharge terminal disposed near metallic controller cover 31 and connected to the power supply ground, the accumulation of static charge to a predetermined threshold level is required and a serge noise at the time of discharge could impair the performance of the electronic devices in the drive control section 13.

Furthermore, the complicated construction is disadvantageous to the motor control apparatus required to reduce the production cost by decreasing the number of component parts and the number of production steps. Accordingly, it is required to relieve the static charge from metallic controller cover 31 to the ground side with a simple construction capable of reducing the number of component parts as much as possible.

The electric fluid pump of this type is disposed in the engine compartment of a motor vehicle. Therefore, rainwater and salt water entering the engine compartment may cause corrosion in the interface between the controller cover 31 and motor housing 23. When minute corrosion proceeds and grows in the interface, the rain water and salt water may enter the chamber in which the control board 32 is disposed, and the inside of motor section 12. Therefore, there arises a possibility of causing short circuit in the electric devices on control board 32 and the windings of motor section 12.

Therefore, to prevent the ingress of water, generally a gasket is interposed between controller cover 31 and motor housing 23.

According to this embodiment, the gasket is utilized, as measure to the problem, in a following construction. Specifically, a conductive gasket is interposed between a metallic housing member such as the metallic controller cover and a resin or plastic housing member such as the resin motor housing, and arranged to remove static electricity by connecting the metallic member with the ground such as the board's side grounding portion of the drive control section.

With the conductive gasket having the grounding function of allowing flow of static charge to the ground portion of the board of the drive control section, as well as the gasket function, the construction can reduce the number of component parts, simplify the construction and prevent influence of serge due to discharge with electric connection always relieving static charge from the controller cover to the ground side of the board.

FIG. 2 shows, in enlarged section, the joint structure between the controller cover 31 and motor housing 23 in the construction according to this embodiment. FIG. 3 shows the joint structure more in detail.

As shown in FIG. 2, the resin motor housing 23 includes a housing joint portion 23A, and the metallic controller cover 31 includes a cover joint portion 31A. Either or both of the joint portions may be in the form of a flange. The housing joint portion 23A of resin motor housing 23 abuts on and contacts with the cover joint portion 31A of controller cover 31. The housing joint portion 23A and cover joint portion 31A are joined together by at least one fastening bolt 34 which is made of metallic material and which is screwed into a metallic insert nut 35 provided in housing joint portion 23A.

The insert nut 35 is inserted in the synthetic resin at the time of molding of the resin motor housing 23. Insert nut 35 is made of metallic material to prevent a fastening force of the fastening bolt 34 from being applied directly to the housing joint portion 23A of the synthetic resin, and thereby to prevent breakage of the housing joint portion 23A. Moreover, the insert nut 35 serves as a conductor for the static electricity, as mentioned later.

A grounding conductive member or grounding terminal forming member 36 is also buried in the synthetic resin by molding at the time of forming the motor housing 23 by molding. The grounding conductive member 36 includes a board side grounding terminal 36A (or bared end segment), a connector side grounding terminal 36B (or bared end segment) and a buried connecting intermediate section or segment 36C connecting both terminals 36A and 36B together.

The board side grounding terminal 36A of grounding conductive member 36 is exposed from motor housing 23 and protruded to be connected with a power supply grounding terminal formed in control board 32. The connector side grounding terminal 36B of grounding conductive member 36 is exposed from a connecting portion 37 of motor housing 23 and adapted to be connected with the vehicle main body. The vehicle main body is used as the ground, and the grounding conductive member 36 is used as a conductor for grounding the control board 32.

FIGS. 3˜7 specifically show the structure and method for joining motor housing 23 and controller cover 31 together. As shown in FIG. 3, the housing joint portion 23A of motor housing 23 includes a joint surface which is adapted to be held in surface contact with a confronting joint surface of the cover joint portion 31A of controller bovver 31. A housing side gasket receiving portion 37 and a cover side gasket receiving portion 38 are formed around insert nut 35, respectively in the joint surfaces of housing joint portion 23A and cover joint portion 31A.

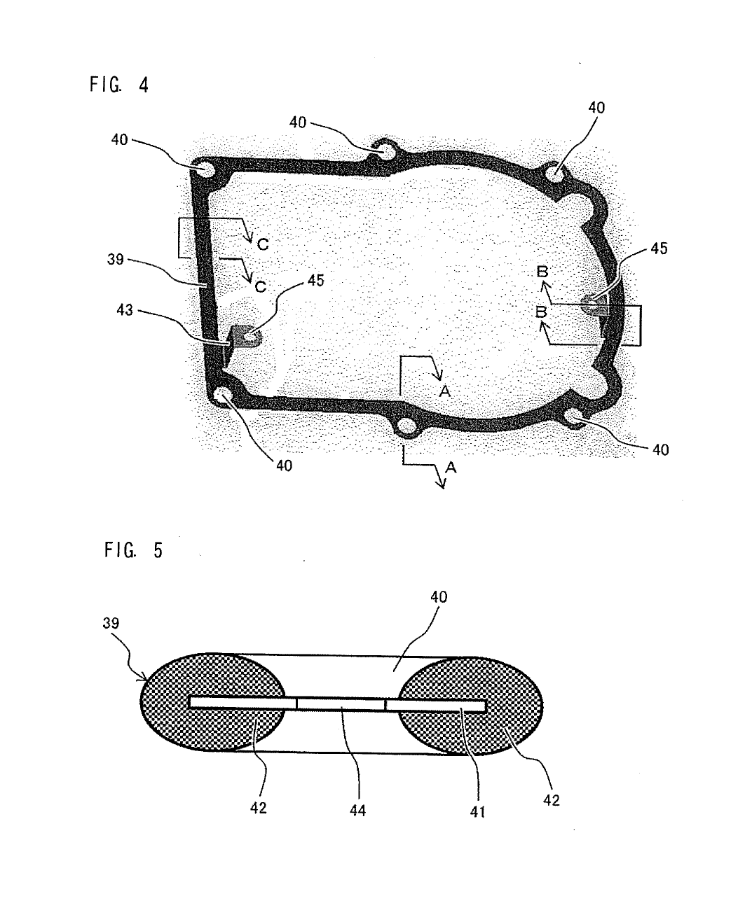

The gasket receiving portions 37 and 38 form an annular space receiving the conductive gasket 39 characteristic of this embodiment. The conductive gasket 39 is constructed as shown in FIGS. 4˜7.

The conductive gasket 39 extends, in the form of a strip, along the mating joint surfaces of the housing joint portion 23A and cover joining surface 31A so as to form a closed figure as shown in FIG. 4, and includes a plurality of joint portions or hole portions 40 each defining a through hole and surrounding a corresponding one of the insert nuts 35. The joint or hole portions 40 are distributed in the circumference of conductive gasket 39. FIG. 3 shows one of the joint portions 40.

The conductive gasket 39 includes strip-like gasket segments and the joint or hole portions 40 (or boss portions), and the gasket segments and joint portions 40 are arranged alternately along the circumference. Each of the gasket segments is shaped like a strip and extends from one of the joint portions 40 to a next one. The conductive gasket 39 extends, to describe the closed figure of FIG. 4, circumferentially around the inside space 30 of the cover 31.

The gasket receiving portions or grooves 37 and 38 formed, respectively, in the joint surfaces of housing joint portion 23A and cover joint portion 31A extend along the conductive gasket 39 and define a gasket receiving space extending circumferentially to form the closed figure as shown in FIG. 4, and having a shape in which the gasket segments and hole portions 40 are fit snugly.

Conductive gasket 39 includes a grounding base member 41 and a seal member 42 (or seal portion) as shown in FIGS. 3˜7. The grounding base member 41 is made of conductive metallic sheet such as copper sheet or aluminum sheet. The seal member 42 is made of material having a good sealing performance such as a rubber material, and formed or fixed on the outside surfaces of grounding base member 41. The grounding base member 41 extends circumferentially along the joint surfaces of joint portions 23A and 31B of motor housing 23 and controller cover 31, so as to form the closed figure of conductive gasket 39 as shown in FIG. 4. Seal member 42 is fixed by baking, for example, on the grounding base member 41.

The seal member 42 of this example is made of rubber material selected from natural rubber, nitrile rubber, chloroprene rubber, ethylene propylene rubber, butyl rubber, silicone rubber, fluororubber, and perfluororubber. It is possible to use other seal material or other rubber material capable of preventing liquid such as water from entering the interface between motor housing 23 and controller cover 31.

Reverting to FIG. 3, the insert nut 35 includes a larger portion 35A having a larger cross sectional size or a larger diameter and a smaller portion 35B having a smaller cross sectional size or a smaller diameter. The smaller portion 35B of insert nut 35 is inserted or fit in a connection hole 44 (shown in FIG. 5) of grounding base member 41 of conductive gasket 39, to make electrical connection therebetween. Therefore, the fastening bolt 34 is electrically connected with the grounding base member 41 when the fastening bolt 34 is tightened into the insert nut 35.

The internally threaded hole of insert nut 35 extends through the smaller portion 35B and the larger portion 35A. The insert nut 35 includes an annular shoulder surface extending around the threaded hole, between the smaller portion 35B and the larger portion 35A and facing toward the joint portion 31A of cover 31. In the example of FIG. 3, the smaller portion 35B abuts on the joint portion 31A of cover 31, and is sandwiched between the joint portion 31A and the larger portion 35A of insert nut 35.

FIG. 5 shows the conductive gasket 39 in section taken across a line A-A shown in FIG. 4. The grounding base member 41 is buried mostly in the material of seal member 42 formed or baked on the surfaces of grounding base member 41 and arranged to server as the gasket. FIG. 5 is the sectional view of conductive gasket 39 at one of the joint portions 40 (or hole portions). Each of joint portions 40 surrounds the smaller portion 35B of one of insert nuts 35B, and has an annular shape. As shown in FIG. 5, the joint portion 40 includes an annular seal portion which is a part of the seal member 42, and an annular conductive portion which is a part of the grounding base member 41. The annular conductive portion of grounding base member 41 includes an outer circumferential portion buried in the annular seal portion and an inner circumferential portion which is projected and bared radially inwards from the annular seal portion and formed with one of connection holes 44, at or near the center. The connection hole 44 of each joint portion 40 is arranged and shaped to receive the smaller portion 35B of insert nut 35 to make electrical connection between the smaller portion 35B of insert nut 35 and the inner circumferential portion of grounding base member 41. Moreover, the bared inner circumferential portion of the annular conductive portion of grounding base member 41 abuts on the controller cover 31, or is clamped between controller cover 31 and an annular portion of motor housing 23 surrounding the smaller portion 35B of inset nut 35, so that electric connection is established between controller cover 31 and grounding base member 41.

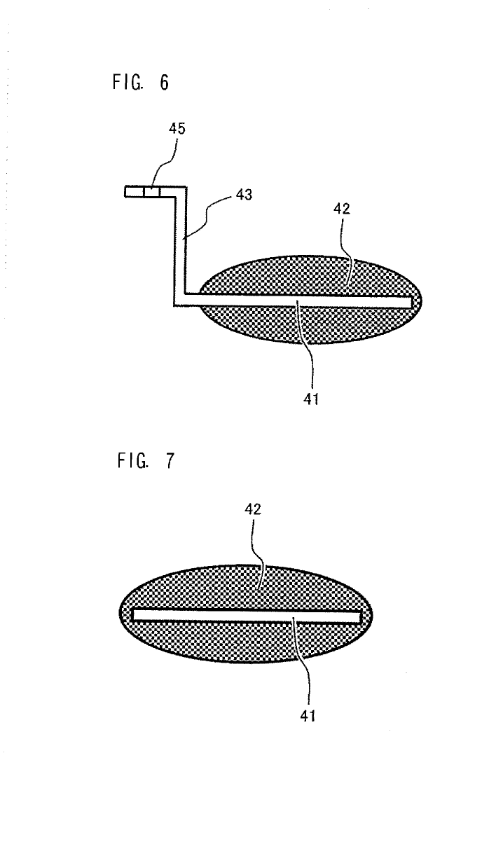

FIG. 6 shows the conductive gasket 39 in section taken across a line B-B shown in FIG. 4. The grounding base member 41 is buried mostly in the material of seal member 42 formed or baked on the surfaces of grounding base member 41 and arranged to server as the gasket. FIG. 6 is the sectional view of conductive gasket 39 at a connect portion formed with a connection terminal 43 to be connected with the board side grounding terminal 36A of grounding conductive member 36. As shown in FIG. 6, the connection terminal 43 is an extended portion of grounding base member 41. The connection terminal 43 extends laterally from the gasket segment, for example, to a forward end portion formed with a connection hole 45 for receiving the board side grounding terminal 36A. In the example of FIG. 4, the connection terminal 43 is formed on the inner side within the space enclosed by the closed figure of the conductive gasket 39. The board side grounding terminal 36A is inserted through the connection hole 45 and arranged to connect the grounding base member 41 and the grounding conductive member 36. Thus, the fastening bolt 34 is connected electrically with the board side grounding terminal 36A through insert nut 35, the through hole 44 of grounding base member 41, grounding base member 41, connection terminal 43 and connection hole 45.

FIG. 7 shows the conductive gasket 39 in section taken across a line C-C shown in FIG. 4. As shown in FIG. 7, the grounding base member 41 is buried in the material of seal member 42 formed or baked on the surfaces of grounding base member 41 and arranged to server as the gasket. The grounding base member 41 serves as a conductor for connecting the insert nut(s) 35 and the board side grounding terminal 36A electrically.

The conductive gasket 39 can be produced by the following method. In this practical example, the grounding base member 41 is formed into the shape shown in FIG. 4 by punching of a copper sheet with a press machine. The grounding base member 41 includes at least one connecting portion including the connecting terminal 43 as shown in FIG. 4. Therefore, the grounding base member 41 is formed by punching into the shape having at least one connecting portion 43. Then, the sealing material such as the rubber material is baked and fixed to the punched copper sheet, to form the seal member 42 having the required shaped. Thereafter, the connecting terminal 43 is bent to the predetermined shape. Thus, the conductive gasket 39 is completed.

The thus-produced conductive gasket 39 is set in the gasket receiving portion 37 of motor housing 23 as shown in FIG. 3. In this case, the annular bared inner circumferential portion of conductive gasket 39 around the hole 44 at each joint portion is fit over the smaller portion 35B of the insert nut 35 and connected electrically with the insert nut 35. The connection hole 45 of the connection terminal 43 of the grounding base member 41 is fit over the board side grounding terminal 36A of grounding conductive member 36 and electrically connected with grounding conductive member 36.

In this state, the control board 32 is fixed and the controller cover 31 is put on the motor housing 23. Then, the controller cover 31 is fastened firmly to motor housing 23 by tightening each fastening bolt 34 into the mating insert nut 35. The connection terminal 43 of grounding base member 41 may be connected with the board side grounding terminal 36A of grounding conductive member 36 on the upper side of control board 32. In this case, the connection terminal 43 is connected with the board side grounding terminal 36A after the board 32 is installed.

Therefore, the seal member 42 of conductive gasket 39 can serve as a seal between the mating joint surfaces of the fixing portions 23A and 31A of motor housing 23 and cover 31. Furthermore, the grounding base member 41 of conductive gasket 39 can make electric connection between fastening bolts 34 and the board side grounding terminal 36A through fastening bolts 34, insert nuts 35, the through holes 44 of grounding base member 41, grounding base member 41, connection terminal 43 and connection hole 45.

When the thus-produced electric fluid pump 10 is installed in a vehicle, static electric charge is created in electric fluid pump 10 as mentioned before, and static electricity accumulated in the surface of controller cover 31 can always flow through the heads of fastening bolts 34 held in contact with controller cover 34.

From the fastening bolts 34, the charge of the static electricity flows into insert nuts 35, and from insert nuts 35, through the through holes 44 of grounding base member 41, grounding base member 41, connection terminal 43 and connection hole 45, to the board side grounding terminal 36A. From the board side grounding terminal 36A, the static electricity flows through the buried connecting portion 3C of grounding conductive member 36, to the connector side grounding terminal 36B.

With the conductive gasket 39 combining the function of the seal and the function of grounding, this embodiment can reduce the number of constituent parts and simplify the construction.

Furthermore, the grounding conductive member 36 is molded together with the motor section 12. Therefore, there is no need for providing a protective member for protecting the grounding conductive member 36, and it is possible to reduce the number of constituent parts and the number of steps in the assembly process.

Fastening bolts 34 are always connected electrically with the board side grounding terminal 36A. Therefore, the static electricity accumulated in controller cover 31 can flow to the board side grounding terminal 36A any time, so that this structure can prevent influence of serge due to a discharge.

In the illustrated practical example, the conductive gasket 39 has the structure composed of the grounding base member 41 and the seal member or seal material 42 fixed on the grounding base member 41 by baking. However, it is possible to produce the conductive gasket 39 by preparing a mixture of conductive metallic power such as silver or copper powder, and a rubber material such as silicone rubber at a predetermined mixing ratio, and forming the conductive gasket from the mixture by extrusion molding or hot press forming. The use of silicone rubber as a binder is advantageous for improving the heat resistance and the sealing performance.

The conductive metal powder can be connected electrically with the connection terminal 43 by burying the connecting terminal 43 in the seal member 42. On the other hand, electrical connection with the controller cover 31 is made by direct contact with the controller cover 31, without the need for additional connection terminal.

According to the first embodiment, the conductive gasket is interposed between the metallic cover and resin housing and arranged to connect the metallic cover with the member for grounding or with the board side grounding terminal to relieve the static electricity to the member for grounding.

With this arrangement, the conductive gasket can serve as the gasket and as the conductor for grounding. Therefore, it is possible to reduce the number of component parts, simplify the construction and prevent discharge and surge.

### Second Embodiment

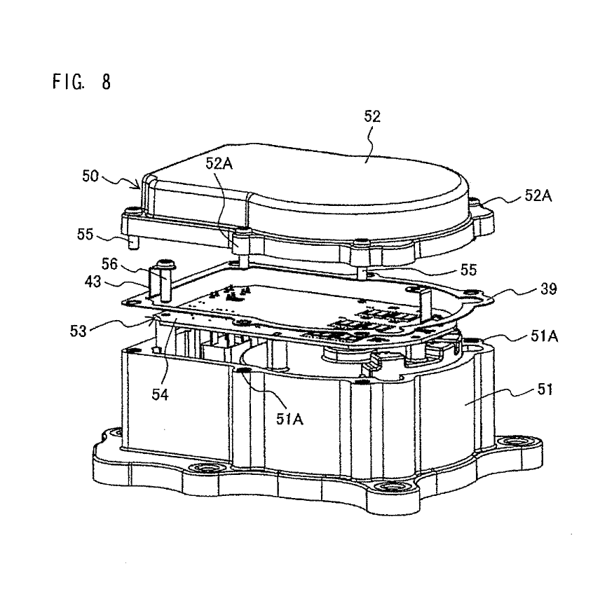

FIG. 8 shows a second embodiment of the present invention. In the second embodiment, a drive control section 53 is enclosed in a casing 50 as an electronic control apparatus not integrated with another apparatus such as a motor or a fluid pump whereas the drive control section 13 according to the first embodiment is integrated with the motor and/or the pump. The arrangement for transferring the static electricity toward the ground is basically the same as the arrangement in the first embodiment, so that the explanation is simplified.

The casing 50 of the electronic control apparatus shown in FIG. 8 includes a controller housing 51 and a controller cover 52. The drive control section 53 is disposed in the inside interspace formed between controller housing 51 and controller cover 52. The drive control section 53 of this example is a driver for supplying a driving current to an electric component such as an electric motor, and includes a control board 54 including electric or electronic device(s). The controller housing 51 is made of a synthetic resin, and the controller cover 52 is a metallic cover made of a metallic material such as aluminum alloy. The metallic controller cover 52 serves as a radiator plate for dissipating heat generated in the drive control section 53.

The control board 54 is a board on and in which electric or electronic device(s) (such as CPU and transistors) are mounted. These electric devices and capacitor(s) form a converter and a control circuit, for example. The converter receives power from a dc power source in the form of a battery and supplies ac power to the windings of a motor, for example. The control circuit includes a microcomputer and other components, for controlling the on-off state of IGBT(s) of the converter.

As shown in FIG. 8, the resin controller housing 51 includes a housing joint portion 51A, and the metallic controller cover 52 includes a cover joint portion 52A. At least one of the joint portions may be in the form of a flange. The housing joint portion 51AA of resin controller housing 51 abuts on and contacts with the cover joint portion 52A of controller cover 52. The housing joint portion 51A and cover joint portion 52A are joined together by at least one fastening bolt 55 which is screwed into a metallic insert nut (not shown in FIG. 8) provided in the controller housing 51. As in the first embodiment, the housing side gasket receiving portion (not shown in FIG. 8) and the cover side gasket receiving portion (not shown in FIG. 8) are formed, respectively in the joint surfaces of housing joint portion 51A and cover joint portion 52A.

The conductive gasket 39 similar to that of the first embodiment is received in the annular space formed by the gasket receiving portions. The conductive gasket 39 extends along the mating joint surfaces of the housing joint portion 51A and cover joining surface 52A so as to form a closed figure as shown in FIG. 4, and includes a plurality of joint portions or hole portions each defining a through hole and surrounding a corresponding one of the insert nuts. The joint or hole portions are distributed in the circumference of conductive gasket 39.

The conductive gasket 39 includes the gasket segments and the joint or hole portions 40 (or boss portions or joint portions), and the gasket segments and joint portions 40 are arranged alternately along the circumference. Each of the gasket segments is shaped like a strip and extends from one of the joint portions to the next.

The gasket receiving space defined by the gasket receiving portions formed, respectively, in the joint surfaces of housing joint portion 51A and cover joint portion 52A—extends along the circumference of conductive gasket 39 to form the closed figure and receives the gasket segments and the joint portions of conductive gasket 39.

Conductive gasket 39 includes the grounding base member 41 of the shaped conductive metal sheet such as copper sheet or aluminum sheet, and the seal member or seal portion 42 as shown in FIGS. 3˜7. The seal member 42 is made of material having a good sealing performance such as a rubber material, and formed or fixed on the outside surfaces of grounding base member 41. The grounding base member 41 extends circumferentially along the joint surfaces of joint portions 51A and 52A of controller motor housing 51 and controller cover 52, so as to form the closed figure of conductive gasket 39 as shown in FIG. 4. Seal member 42 is fixed by baking, for example, on the thus-constructed grounding base member 41.

As in the first embodiment shown in FIG. 3, each insert nut 35 includes the larger portion having a larger cross sectional size or a larger diameter and teh smaller portion having a smaller cross sectional size or a smaller diameter. The smaller portion of insert nut 35 is inserted or fit in the connection hole of grounding base member 41 of conductive gasket 39, to make electrical connection therebetween. Therefore, the fastening bolt 55 is electrically connected with the grounding base member 41 when the fastening bolt 34 is tightened into the insert nut.

The grounding base member 41 is buried mostly in the material of seal member 42 which is formed or baked on the surfaces of grounding base member 41 and which is arranged to server as the gasket. As shown in FIG. 6, the connection terminal 43 of grounding base member 41 extends laterally from one of the gasket segments, and then extends upwards as viewed in FIG. 6, to the forward end portion bent and formed with the connection hole 45. This connection hole 45 of the forward end portion of connection terminal 43 of grounding base member 41 of conductive gasket 39 is connected electrically with the board side grounding terminal (not shown in FIG. 8) by a connection bolt 56 shown in FIG. 8. Thus, the controller cover 51 is electrically connected with the board side grounding terminal through the fastening bolts 55, the insert nuts, the grounding base member 41, and connection bolt(s) 56.

When the thus-produced casing 50 of the electronic control apparatus is installed in a vehicle, static electric charge is created in casing 50 as mentioned before, and static electricity accumulated in the surface of controller cover 52 can always flow through the heads of fastening bolts 55 contacting with controller cover 52.

From the fastening bolts 55, the static electricity flows into the insert nuts, and further flows from the insert nuts, through the grounding base member 41, and the connecting bolt 56, to the board side grounding terminal of the grounding conductive member.

With the conductive gasket 39 combining the function of the seal and the function of grounding, the second embodiment can reduce the number of constituent parts and simplify the construction like the first embodiment. Furthermore, the fastening bolts 55 are always connected electrically with the board side grounding terminal. Therefore, the static electricity accumulated in controller cover 52 can flow to the board side grounding terminal any time, so that this structure can prevent influence of serge due to a discharge.

In the second embodiment, the motor drive control section for the motor is enclosed in the casing of the electronic control apparatus. However, it is optional to enclose any of various control circuit sections in the casing.

As explained above, an electronic control apparatus according to the present invention comprises a resin housing, a metallic cover, and a conductive gasket interposed between a joint surface of the resin housing and a joint surface of the metallic cover, and arranged to ground the metallic cover electrically through the conductive gasket, to a ground or to a grounding conductive member for electrical grounding or to a board side grounding terminal.

With this arrangement, the conductive gasket can serve as a gasket, and at the same time serve as an electric conductor for conducting static electricity to the ground or to the grounding conductive member. Therefore, it is possible to reduce the number of component parts, to simplify the construction and the production process, and to prevent the influence of serge due to discharge.

The present invention contains various modifications and variations, and the present invention is not limited to the illustrated embodiments. It is possible to omit part of the constructions of the illustrated embodiments, to add one or more additional features, to replace the features of the illustrated embodiments with different features or to replace one or more features of one embodiment with one or more features of another embodiment.

The electronic control apparatus according to the present invention may be a motor control apparatus comprising a resin motor housing enclosing a motor including a rotor and a stator, a drive control section including a circuit to supply a drive signal to winding(s) of the stator and thereby to control rotation of the rotor, and a metallic cover arranged to cover the drive control section and joined to the motor housing by at least one fastening bolt through a conductive gasket arranged to connect the metallic cover to a member for grounding. The electronic control apparatus according to the present invention may be an electric fluid pump comprising a pump section to transfer a fluid, a resin motor housing enclosing a motor to drive the pump section (an impeller of the pump section), a drive control section to control the motor, and a metallic cover arranged to cover the drive control section and joined to the motor housing by at least one fastening bolt through a conductive gasket arranged to connect the metallic cover to a member for grounding.

According to one aspect of the present invention, an electronic control apparatus (such as a motor control apparatus or an electric fluid pump) comprises: a housing of synthetic resin; a cover of metallic material, fixed to the housing by a fastening bolt; an electronic control section (which may include an electronic control board) enclosed in an interspace formed between the housing and the cover; and a conductive gasket interposed or clamped between a joint surface of the housing and a joint surface of the cover to fill a clearance between the mating joint surfaces, and arranged to ground the cover electrically through the conductive gasket. The conductive gaskets includes a grounding base member of conductive metallic material arranged to connect the cover with a grounding conductive member for electrical grounding, and a seal member or seal portion covering the grounding base member (and serving as a gasket or seal). The electronic control apparatus may further comprise the grounding conductive member formed or buried (by insert molding, for example) in the synthetic resin of the housing and connected electrically with the grounding base member. The electronic control apparatus may further comprise an insert nut made of a metallic material, formed fixedly in the synthetic resin of the housing, and arranged to join the cover to the housing with the fastening bolt screwed into an internally threaded hole of the insert nut, and to make electrical connection from the cover, through the fastening bolt and the insert nut, to the grounding base member of the conductive gasket.

The grounding base member of the conductive gasket may include an annular portion surrounding the fastening bolt (or an insert nut), and the seal member may include a first (upper) annular portion formed on a first (upper) surface of the annular portion of the grounding base member, and received in an annular groove formed in the joint surface of the cover and a second (lower) annular portion formed on a second (lower) surface of the annular portion of the grounding base member, and received in an annular groove formed in the joint surface of the housing, and the annular portion of the grounding base member may include an outer circumferential region buried in the synthetic resin between the first and second annular portions of the seal member, and an inner circumferential region bared from the synthetic resin of the seal member and clamped between the cover and the housing to make electrical connection between the cover and the grounding base member. In the example of FIG. 3, the bared inner circumferential region of the annular portion of the grounding base member (41) is clamped directly between the joint portion (31A) of the cover (31) and the joint portion (23A) of the housing (23). The electronic control section may include a control board supported by the housing and covered by the cover, and the electronic control apparatus may further comprise the grounding conductive member (36) including a board side grounding terminal (36A) bared from the synthetic resin of the housing, and connected with the control board, an intermediate buried segment (36C) buried in the synthetic resin of the housing and a ground side terminal (36B) adapted to be connected with a predetermined member serving as a ground, and the grounding base member of the conductive gasket may include a connecting projection connected with the board side grounding terminal of the grounding conductive member.

1. An electronic control apparatus comprising:
a housing of synthetic resin;
a cover of metallic material, fixed to the housing by a fastening bolt;
an electronic control section enclosed in an interspace formed between the housing and the cover; and
a conductive gasket interposed between a joint surface of the housing and a joint surface of the cover, and arranged to ground the cover electrically through the conductive gasket.

2. The electronic control apparatus as claimed in claim 1, wherein the conductive gasket comprises a grounding base member of conductive metallic material for electric conduction, and a seal member covering the grounding base member, and the conductive gasket is arranged to connect the cover, through the grounding base member, to a grounding portion for electrical grounding.

3. The electronic control apparatus as claimed in claim 2, wherein the electronic control apparatus further comprises an insert nut formed in the synthetic resin of the housing, arranged to fasten the cover to the housing with the fastening bolt screwed into the insert nut, and connected electrically with the grounding base member of the conductive gasket.

4. The electronic control apparatus as claimed in claim 2, wherein the grounding base member of the conductive gasket includes a bared portion bared from the seal member and set in contact with the cover.

5. The electronic control apparatus as claimed in claim 4, wherein the bared portion of the grounding base member of the conductive gasket is an annular portion which surround the fastening bolt and which is clamped between the cover and the housing.

6. The electronic control apparatus as claimed in claim 2, wherein the grounding base member of the conductive gasket includes a connecting terminal connected with a grounding conductive member adapted to be connected to a ground.

7. The electronic control apparatus as claimed in claim 6, wherein the grounding conductive member is formed in the synthetic resin of the housing and includes a board side grounding terminal connected with a portion of an electronic control board of the electronic control section for grounding, and a ground side terminal adapted to be connected to the ground, and the connecting terminal of the grounding base member of the conductive gasket is connected with the grounding conductive member.

8. The electronic control apparatus as claimed in claim 2, wherein the seal member is made of a rubber material which is one of natural rubber, nitrile rubber, chioroprene rubber, ethylene-propylene rubber, butyl rubber, silicone rubber, fluororubber, and perfluororubber.

9. The electronic control apparatus as claimed in claim 1, wherein the housing is a motor housing enclosing a motor including a rotor and a stator, and the control section includes a drive control circuit to supply a drive signal to a winding of the stator and thereby to control rotation of the rotor.

10. The electronic control apparatus as claimed in claim 9, wherein the electronic control apparatus is an electric fluid pump comprising a pump section to transfer a fluid, the motor arranged to drive the pump section and enclosed in the motor housing, and the control section covered by the cover.

11. An electronic control apparatus comprising:
a housing of synthetic resin;
a cover of metallic material, fixed to the housing by a fastening bolt;
an electronic control section enclosed in an interspace formed between the housing and the cover; and
a conductive gasket interposed between a joint surface of the housing and a joint surface of the cover to fill a clearance between the joint surfaces, and arranged to ground the cover electrically through the conductive gasket, the conductive gasket including
a grounding base member of conductive metallic material arranged to connect the cover with a grounding conductive member for electrical grounding, and
a seal member covering the grounding base member.

12. The electronic control apparatus as claimed in claim 11, wherein the electronic control apparatus further comprises the grounding conductive member formed in the synthetic resin of the housing and connected electrically with the grounding base member of the conductive gasket.

13. The electronic control apparatus as claimed in claim 11, wherein the electronic control apparatus further comprises an insert nut made of a metallic material, formed fixedly in the synthetic resin of the housing, and arranged to join the cover to the housing with the fastening bolt screwed into an internally threaded hole of the insert nut, and to make electrical connection from the cover, through the fastening bolt and the insert nut, to the grounding base member of the conductive gasket.

14. The electronic control apparatus as claimed in claim 11, wherein the grounding base member of the conductive gasket includes an annular portion surrounding the fastening bolt, and the seal member includes a first annular portion formed on a first surface of the annular portion of the grounding base member, and received in an annular groove formed in the joint surface of the cover and a second annular portion formed on a second surface of the annular portion of the grounding base member, and received in an annular groove formed in the joint surface of the housing, and the annular portion of the grounding base member includes an outer circumferential region buried between the first and second annular portions of the seal member, and an inner circumferential region bared from the synthetic resin of the seal member and clamped between the cover and the housing.

15. The electronic control apparatus as claimed in claim 11, wherein the electronic control section includes a control board supported by the housing and covered by the cover, and the electronic control apparatus further comprises the grounding conductive member including a board side grounding terminal bared from the synthetic resin of the housing, and connected with the control board, an intermediate buried segment buried in the synthetic resin of the housing and a ground side terminal adapted to be connected with a predetermined member serving as a ground, and the grounding base member of the conductive gasket includes a connecting projection connected with the board side grounding terminal of the grounding conductive member.
